(19) United States
(12) Patent Application Publication
(10) Pub. No.: US 2014/0253091 A1
(43) Pub. Date: Sep. 11, 2014

(54) DETERMINATION DEVICE, DETERMINATION METHOD, AND NON-TRANSITORY RECORDING MEDIUM

(71) Applicants: Masahiro Ishihara, Tokyo (JP); Yoshiaki Koizumi, Tokyo (JP); Masaki Takata, Tokyo (JP)

(72) Inventors: Masahiro Ishihara, Tokyo (JP); Yoshiaki Koizumi, Tokyo (JP); Masaki Takata, Tokyo (JP)

(73) Assignee: MITSUBISHI ELECTRIC CORPORATION, Tokyo (JP)

(21) Appl. No.: 14/350,161

(22) PCT Filed: Oct. 28, 2011
(86) PCT No.: PCT/JP2011/075006

§ 371 Date: Apr. 7, 2014

(51) Int. Cl. G01R 31/04; G01R 25/00

(52) U.S. Cl. CPC G01R 31/041; G01R 25/00
USPC 324/66

(57) ABSTRACT

A power measuring device stores in a set phase relation storage whether the load connected to a three-phase, four-wire power source is inductive, capacitive, or neither of them, in other words whether the phase currents are ahead, delayed, or matching phases with respect to the phase voltages, and determines whether the stored phase relation coincides with the determined phase relation. Then, the incorrect connection that cannot be verified in the prior art, more specifically the primary conductors of the current transformers of the current xfrms that are all arranged reversely while the voltage terminals are connected correctly, can be detected as an incorrect arrangement.

### CROSS REFERENCE TO RELATED APPLICATION

This application is a U.S. national stage application of International Patent Application No. PCT/JP2011/075006 filed on Oct. 28, 2011.

### TECHNICAL FIELD

The present disclosure relates to a determination device, determination method, and a non-transitory recording medium.

### BACKGROUND

The connection state detection device described in Patent Literature 1 is known as a device detecting incorrect connection/arrangement of the terminals connected to power lines to measure the alternating-current voltages, and the incorrect arrangement of the current transformers disposed at an outer circumference of the power lines to measure the alternating currents, in order to measure the alternating-current power supplied from a three-phase alternating-current power source via the power lines.

The connection state detection device described in the Patent Literature 1 determines whether the effective values of the alternating-current voltages in the respective phases are within a given range, and determines whether the phase sequence is the same as a predetermined sequence, based on the alternating-current voltages in the respective phases that are measured by terminals connected to the power lines. The connection state detection device further determines whether the phase differences between the alternating currents and alternating-current voltages of the respective phases are within a predetermined range, and whether there is no input of the alternating current or alternating-current voltage, based on the alternating currents of the respective phases that are measured by current transformers disposed at the outer circumference of the power lines and the alternating-current voltages in the respective phases that are measured by connecting terminals.

Then, the connection state detection device detects incorrect connection of the terminals or incorrect arrangement of the current transformers in any of the following cases: the effective values in the respective phases are outside a given range, the phase sequence is different from a predetermined sequence, the phase differences between the alternating currents and alternating-current voltages in the respective phases are outside a predetermined range, and there is no input of the alternating current or alternating-current voltage.

### CITATION LIST

### Patent Literature

Patent Literature 1; Unexamined Japanese Patent Application Kokai Publication No. 2000-258484.

### Technical Problem

The primary conductors (primary sides) of the current transformers used in the connection state detection device described in the Patent Literature 1 have to be arranged in the correct orientation with respect to the current flowing through the power lines. This is because, if the primary conductor of a current transformer is arranged in the opposite direction to the current flowing through the power line, the alternating current measured will have the reversed phases with respect to the alternating current that is measured under the correct orientation of the primary conductor of the current transformer. Therefore, when the primary conductors of the current transformers disposed at the outer circumference of the power lines are all arranged in the opposite direction, namely in the incorrect arrangement, the alternating currents of all phases then have reversed phases with respect to the alternating currents under the correct orientation. In such a case, if the terminals are all connected correctly to the power lines, the phase differences between the alternating currents and alternating-current voltages of the respective phases may be within a predetermined range depending on the power factor of the load connected to the three-phase alternating-current power source. In such a case, the connection state detection device determines whether the phase differences between the alternating currents and alternating-current voltages in the respective phases are within a predetermined range. Furthermore, since the terminals are all connected correctly, the connection state detection device determines that there is no problem with the other determining factors (whether the effective values in the respective phases are within a given range, whether the phase sequence coincides with a predetermined sequence, and whether there is no alternating current or alternating-current voltage input).

Then, a problem is that even if an error occurs, the connection state detection device described in the Patent Literature 1 fails to detect the error as described above, in other words the accuracy of error detection is low.

### SUMMARY

The present invention is invented with the view of the above situation and an exemplary objective of the present invention is to provide a determination device, determination method, and program realizing high accuracy of error detection.

In order to achieve the above objective, the voltmeter of the determination device according to the present disclosure measures alternating-current voltages of the respective phases that are applied across power lines via terminals connected to the power lines transferring an alternating-current power supplied from a three-phase alternating-current power source. The current meter measures the alternating currents of the respective phases that flow through the power lines via current transformers disposed at an outer circumference of the power lines. The phase relation verifier ascertains a phase relation of the alternating currents with the alternating-current voltages for the respective phases based on the alternating currents measured by the current meter and the alternating-current voltages measured by the voltmeter, and confirms a non-conformity indicating an incorrect connection of the terminals or an incorrect arrangement of the current transformers unless the phase relation ascertained for the respective phases coincides with a preset relation.

The present disclosure determines the phase relation of the alternating currents with the alternating-current voltages and confirms a non-conformity indicating an incorrect connection of the terminals or an incorrect arrangement of the current transformers unless the determined phase relation coincides with a preset relation, thereby realizing high accuracy of error detection compared with the prior art.

### BRIEF DESCRIPTION OF DRAWINGS

FIG. 1 is a block diagram of the power measuring device according to an embodiment of the present invention;

FIG. 2 is an illustration showing the configuration of the storage of the power measuring device;

FIG. 3 is a flowchart of the setting procedure executed by the calculation controller of the power measuring device;

FIG. 4 is a flowchart of the connection detection procedure executed by the calculation controller of the power measuring device;

FIG. 5 is a flowchart of the voltage terminals verification procedure executed by the calculation controller of the power measuring device;

FIG. 6 is a flowchart of the current xfrms verification procedure executed by the calculation controller of the power measuring device;

FIG. 7 is an illustration showing the connection of the voltage terminals of the power measuring device;

FIG. 8 is an illustration showing the placement of the current xfrms of the power measuring device (when the voltage terminals are connected correctly); and

FIG. 9 is an illustration showing the placement of the current vfrms of the power measuring device (when the voltage terminals are connected incorrectly).

### DETAILED DESCRIPTION

A power measuring device 1 according to an embodiment of the present invention will be described hereafter with reference to the drawings. The power measuring device 1 can detect incorrect connection of voltage terminals 3a to 3d and incorrect arrangement of current transformers (current xfmrs) 4a to 4c with high accuracy compared with the prior art.

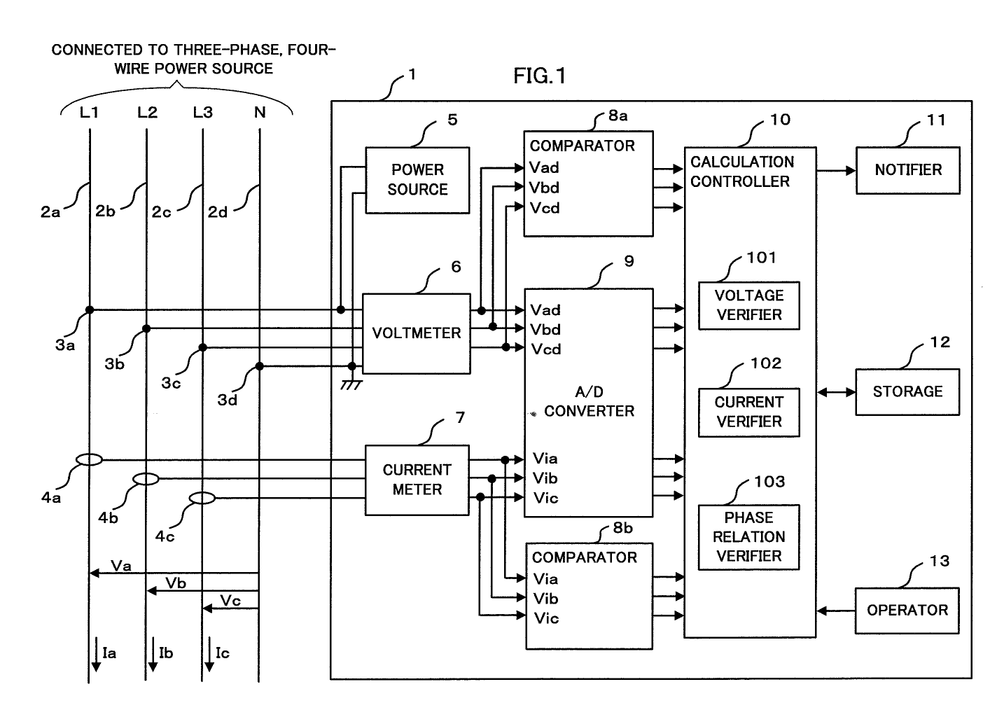

The power measuring device 1 is a device measuring the alternating-current power supplied using power lines 2a to 2d electrically connected to a Y-connection, three-phase, four-wire power source as shown in FIG. 1. Here, an N power line 2d is a power line to which a reference voltage for the alternating-current voltages supplied using L1 to L3 power lines 2a to 2c, is applied (the power line connected to the ground of the power measuring device 1).

The power measuring device 1 comprises voltage terminals 3a to 3d, current xfmrs 4a to 4c, a power source 5, a voltmeter 6, a current meter 7, comparators 8a and 8b, an A/D converter 9, a calculation controller 10, a notifier 11, a storage 12, and an operator 13.

The voltage terminals 3a to 3d are used to measure the alternating-current voltages in the respective phases that are applied across the L1 to L3 power lines 2a to 2c transferring the alternating-current power supplied from the three-phase, four-wire power source, namely the phase voltages Va to Vc. The voltage terminals 3a to 3c are electrically connected to the L1 to L3 power lines 2a to 2c, respectively, and the power terminal 3d is electrically connected to the N power line 2d. With the voltage terminals 3a to 3d being electrically connected to the power lines 2a to 2d, the power measuring device 1 measures the phase voltages Va to Vc. More specifically, using the voltage terminal 3d as the reference, the power measuring device 1 measures the phase voltage Va between the voltage terminals 3a and 3d, the phase voltage Vb between the voltage terminals 3b and 3d, and the phase voltage Vc between the voltage terminals 3c and 3d.

The current xfmrs 4a to 4c each have an annular current transformer with a primary conductor and a secondary conductor, generate alternating currents for the respective phases that flow through the L1 to L3 power lines 2a to 2c, namely voltages corresponding to the phase currents Ia to Ic, at the primary conductors (the primary sides), and generate voltages proportional to the generated voltages at the secondary conductors (the secondary sides). The current xfmrs 4a to 4c are placed so that the annular current transformers surround the L1 to L3 power lines 2a to 2c. With the current xfmrs 4a to 4c being placed around the L1 to L3 power lines 2a to 2c, the power measuring device 1 measures the phase currents Ia to Ic from the voltages generated at the secondary conductors. More specifically, the power measuring device 1 measures the phase current Ia flowing through the L1 power line 2a using the current xfmr 4a, measures the phase current Ib flowing through the L2 power line 2b using the current xfmr 4b, and measures the phase current Ic flowing through the L3 power line 2c using the current xfmr 4c.

Here, in order to measure the phase currents Ia to Ic, the primary conductors of the current transformers of the current xfmrs 4a to 4c should be arranged in the correct orientation with respect to the phase currents Ia to Ic. This is because the alternating currents, if the primary conductors of the current transformers of the current xfmrs 4a to 4c are arranged opposite direction to the phase currents Ia to Ic, have the reversed phases with respect to the alternating currents of under the correct orientation, whereby the power measuring device 1 fails to measure the power correctly.

The power source 5 generates direct-current power using the alternating-current power supplied from the three-phase, four-wire power source, and supplies the generated direct-current power to the components 6 to 13. The power source 5 has two input terminals; one is electrically connected to the L1 power line 2a and the other is electrically connected to the N power line 2d (ground). With the input terminals connected so, the power source 5 rectifies the input phase voltage Va and phase current Ia using, for example, a diode to generate direct-current power. Here, the supply lines through which the power source 5 supplies the generated direct-current power to the components 6 to 13 are omitted in the figure.

The voltmeter 6 measures the phase voltages Va to Vc, and divides and outputs the measured phase voltages Va to Vc to the comparator 8a and A/D converter 9. The voltmeter 6 has four input terminals, which are electrically connected to the voltage terminals 3a to 3d, respectively. Using the four input terminals, the voltmeter 6 measures the phase voltages Va to Vc. Furthermore, the voltmeter 6 has three output terminals, which are each electrically connected to the comparator 8a and A/D converter 9. The voltmeter 6 outputs partial voltages Vad to Vcd measured by dividing the measured phase voltages Va to Vc to the comparator 8a and A/D converter 9 using the three output terminals.

The current meter 7 divides the voltages generated by the current xfmrs 4a to 4c (the secondary conductors of the current transformers) in accordance with the phase currents Ia to Ic flowing through the L1 to L3 power lines 2a to 2c, and outputs the voltages to the comparator 8b and A/D converter 9. The current meter 7 has three input terminals, which are electrically connected to the current xfmrs 4a to 4c (the secondary conductors of the current transformers), respectively. Using the three input terminals, the current meter 7 measures the phase currents Ia to Ic. Furthermore, the current meter 7 has three output terminals, which are each electrically connected to the comparator 8b and A/D converter 9. The current meter 7 divides the voltages generated by the current xfmrs 4a to 4c (the secondary conductors of the current transformers) in accordance with the phase currents Ia to Ic using, for example, a resistor into converted voltages Via to Vic, and outputs the converted voltages Via to Vic to the comparator 8b and A/D converter 9 using the three output terminals.

The comparator 8a has three input terminals, which are electrically connected to the three output terminals of the voltmeter 6, and has three output terminals, which are connected to the calculation controller 10. The comparator 8a compares the partial voltages Vad to Vcd output from the voltmeter 6 with the ground voltage. The comparator 8a outputs, for each of the partial voltages Vad to Vcd (for each phase), a positive direct-current voltage to the calculation controller 10 when the partial voltage is positive, and outputs, for each of the partial voltages Vad to Vcd, a voltage of zero to the calculation controller 10 when the partial voltage is negative.

The comparator 8b has three input terminals, which are electrically connected to the three output terminals of the current meter 7, and has three output terminals, which are connected to the calculation controller 10. The comparator 8b compares the converted voltages Via to Vic output from the current meter 7 with the ground voltage. The comparator 8b outputs, for each of the converted voltages Via to Vic (for each phase), a positive direct-current voltage to the calculation controller 10 when the converted voltage is positive, and outputs, for each of the converted voltages Via to Vic, a voltage of zero to the calculation controller 10 when the partial voltage is negative.

Here, the comparators 8a and 8b each have low-pass filters (not shown) at the stage subsequent to the input terminals in order to control distortion of the voltage waveform entered from the input terminals.

The A/D converter 9 has six input terminals, which are connected to the three output terminals of the voltmeter 6 and three output terminals of the current meter 7, and has six output terminals, which are connected to the calculation controller 10. The A/D converter 9 converts values of the partial voltages Vad to Vcd (instantaneous values) output from the voltmeter 6, and converts values of the converted voltages Via to Vic (instantaneous values) output from the current meter 7, from an analog value to a digital value, then outputs the each value to the calculation controller 10.

Here, a trigger signal output from the calculation controller 10 to the A/D converter 9 is used to control the sampling in which the A/D converter 9 converts the values of the partial voltages Vad to Vcd and the values of the converted voltages Via to Vic from analog values to digital values. Here, the phase currents Ia to Ic are the leading phases that occur ahead of the phase voltages Va to Vc under the influence of the current transformers of the current xfmrs 4a to 4c. Therefore, the A/D converter 9 takes samples of the values of the converted voltages Via to Vic prior to the sampling of the values of the partial voltages Vad to Vcd by this phase advancement. Values of the sampled (digitalized) partial voltages Vad to Vcd and the values of the converted voltages Via to Vic are output from the A/D converter 9 and stored in the RAM of the calculation controller 10.

The calculation controller 10 comprises a CPU (central processing unit), a ROM (read only memory), and a RAM (random access memory) (none of them are shown), and has 14 input terminals, which are connected to the comparators 8a and 8b, A/D converter 9, storage 12, and operator 13, and two output terminals, which are connected to the notifier 11 and storage 12.

The calculation controller 10 stores values of the direct-current voltages output from the comparator 8a in the RAM (not shown) of the calculation controller 10 in association with each output time. The calculation controller 10 measures time at which the phase voltages Va to Vc are reached zero (zero-crossing time based on information stored in the RAM, more specifically based on time at which a positive direct-current voltage turns into a voltage of zero and the time at which a direct-current voltage of zero turns into a positive direct-current voltage.

The calculation controller 10 stores the values of the direct-current voltage output from the comparator 8b in the RAM (not shown) of the calculation controller 10 in association with each output time. The calculation controller 10 measures time at which the phase currents Ia to Ic are reached zero (zero-crossing time) based on information stored in the RAM, more specifically, based on time at which a positive direct-current voltage turns into a voltage of zero and the time at which a direct-current voltage of zero turns into a positive direct-current voltage.

The RAM (not shown) temporarily stores the values of the partial voltages Vad to Vcd and the values of the converted voltages Via to Vic output from the A/D converter 9 in addition to information the calculation controller 10 has created by associating the direct-current voltages of the respective phases that are output from the comparators 8a and 8b with the time.

The calculation controller 10 executes the programs stored in the ROM (not shown) to realize the functions of a voltage verifier 101, a current verifier 102, and a phase relation verifier 103.

The voltage verifier 101 ascertains the effective values of the phase voltages Va to Vc based on the values of the partial voltages Vad to Vcd (corresponding to the phase voltages Va to Vc) output from the A/D converter 9 and determines whether the determined effective values are within an acceptable range.

Furthermore, the voltage verifier 101 ascertains the zero-crossing time of the phase voltages Va to Vc from information stored in the RAM (not shown), namely information created by associating the values of the direct-current voltages of the respective phases that are output from the comparator 8a with the time. Then, the voltage verifier 101 ascertains the phase sequence of the phase voltages Va, Vb, and Vc (the order in which the phase voltages reach zero volt), and determines whether the determined sequence coincides with a preset sequence.

In other words, the voltage verifier 101 ascertains the vector relation of the measured alternating-current voltages (the relation between the effective value and the phase sequence for the phase voltages Va to Vc) from the values of the partial voltages Vad to Vcd output from the A/D converter 9 (corresponding to the phase voltages Va to Vc), and determines whether the determined vector relation coincides with the vector relation of the alternating-current voltages (phase voltages Va to Vc) applied across the power lines 3a to 3c by the three-phase alternating-current power source using the effective values and phase sequence.

The current verifier 102 ascertains the phase differences between the phase currents Ia to Ic and phase voltages Va to Vc (0 degree to 180 degrees) for the respective phases based on information stored in the RAM (not shown), namely information created by associating the values of the direct-current voltages for the respective phases that are output from the comparator 8a with the time, and based on information created by associating the values of the direct-current voltages of the respective phases that are output from the comparator 8b with the time, and determines whether the determined phase differences are within preset ranges. Here, since the phase currents Ia to Ic are the leading phase that occur ahead of the phase voltages Va to Vc under the influence of the current transformers of the current xfmrs 4a to 4c, the current verifier 102 assumes that the zero-crossing time for the phase currents Ia to Ic occurs prior to the zero-crossing time of the phase voltages Va to Vc by this phase advancement.

Furthermore, the current verifier 102 calculates power for the respective phases (phase power) Pa to Pc supplied via the L1 to L3 power lines 2a to 2c using the values of the partial voltages Vad to Vcd (corresponding to the phase voltages Va to Vc) and the values of the converted voltages Via to Vic (corresponding to the phase current Ia to Ic) output from the A/D converter 9, and determines whether the calculated phase power Pa to Pc is positive (not zero).

The phase relation verifier 103 ascertains, for the respective phases, the phase relation, namely whether the phase currents Ia to Ic are ahead, delayed, or matching phases with respect to the phase voltages Va to Vc (the phase relation of the phase currents Ia to Ic to the phase voltages Va to Vc) based on the zero-crossing time of the phase currents Ia to Ic and phase voltages Va to Vc, and determines whether the determined phase relation coincides with a preset phase relation.

The calculation controller 10 determines whether the voltage terminals 3a to 3d are connected to the power lines 2a to 2d correctly and the current xfmrs 4a to 4c are correctly arranged on the power lines 2a to 2c using the determination results of the voltage verifier 101, current verifier 102, and phase relation verifier 103. If the connection is correct and the arrangement is correct, the calculation controller 10 gives notice of the phase power Pa to Pc using the notifier 11.

The notifier 11 is, for example, a liquid crystal display, and displays incorrect connection and/or incorrect arrangement for notification when the voltage terminals 3a to 3d and current xfmrs 4a to 4c are incorrectly arranged (more specifically, at least one of the voltage verifier 101, current verifier 102, and phase relation verifier 103 yields a determination result of being incorrect). On the other hand, the notifier 11 displays the calculated phase power Pa to Pc when the voltage terminals 3a to 3d and current xfmrs 4a to 4c are arranged correctly.

The storage 12 stores information necessary for the calculation controller 10 to determine whether the voltage terminals 3a to 3d are connected to the power lines 2a to 2d correctly and the primary conductive wires of the current transformers of the current xfmrs 4a to 4c are arranged on the power lines 2a to 2c in the correct orientation.

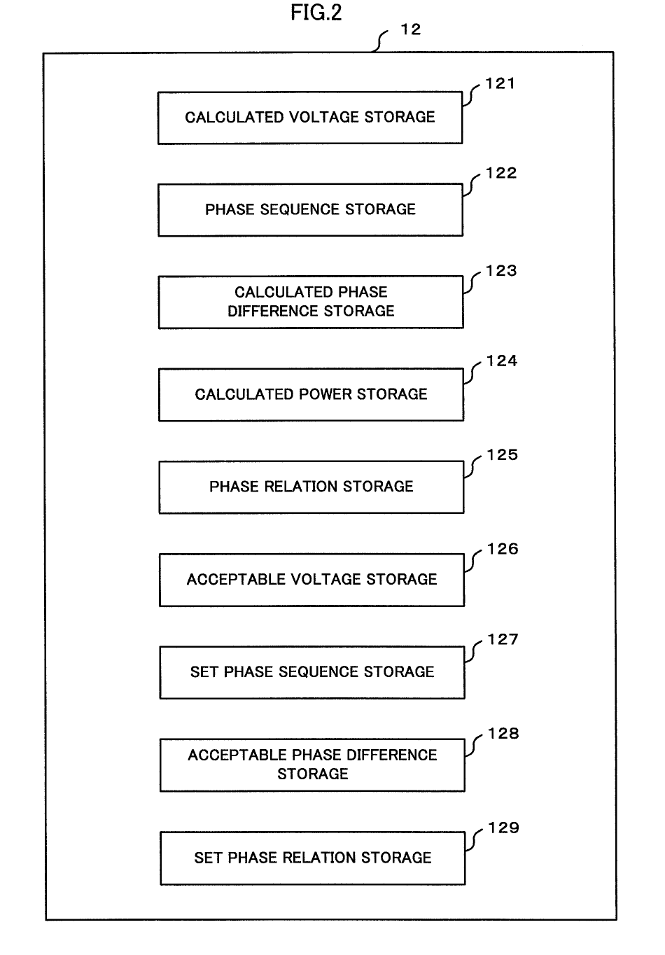

The storage 12 is constituted by a flash memory and comprises, as shown in FIG. 2, a calculated voltage storage 121, a phase sequence storage 122, a calculated phase difference storage 123, a calculated power storage 124, a phase relation storage 125, an acceptable voltage storage 126, a set phase sequence storage 127, an acceptable phase difference storage 128, and a set phase relation storage 129.

The calculated voltage storage 121 stores, for the respective phases, the effective values of the phase voltages Va to Vc that are calculated by the voltage verifier 101.

The phase sequence storage 122 stores the phase sequence of the phase voltages Va, Vb, and Vc that is ascertained by the voltage verifier 101.

The calculated phase difference storage 123 stores, for the respective phases, the phase differences between the phase currents Ia to Ic and phase voltages Va to Vc that are calculated by the current verifier 102.

The calculated power storage 124 stores, for the respective phases, the phase power Pa to Pc calculated by the current verifier 102.

The phase relation storage 125 stores, for the respective phases, the phase relation ascertained by the phase relation verifier 103, more specifically whether the phase currents Ia to Ic are ahead, delayed, or matching phases with respect to the phase voltages Va to Vc.

The acceptable voltage storage 126 stores a range in which the effective values of the phase voltages Va to Vc are acceptable (“the acceptable effective value,” hereafter). Here, the acceptable effective value is set using the operator 13 to, for example, “a range of ±20% of the phase voltages Va to Vc stored in the calculated voltage storage 121.”

The set phase sequence storage 127 stores a set phase sequence that is used by the voltage verifier 101 to determine whether the phase sequence of the phase voltages Va, Vb, and Vc stored in the phase sequence storage 122 is the correct sequence (coincide with the set phase sequence). Here, the set phase sequence is set using the operator 13 to, for example, “the order of Phase voltage Va→Phase voltage Vb→Phase voltage Vc.”

The acceptable phase difference storage 128 stores, for the respective phases, ranges from 0 degree to 180 degrees in which the phase differences between the phase currents Ia to Ic and phase voltages Va to Vc are acceptable (“the acceptable phase differences,” hereafter). Here, the acceptable phase differences are set using the operator 13 to, for example, “the phase differences between the phase currents Ia to Ic and corresponding phase voltages Va to Vc being within a range from 0 degree to 60 degrees in all phases.”

The set phase relation storage 129 stores the phase relation in the respective phases that is used by the phase relation verifier 103 to determine whether the phase relation in the respective phases (whether the phase currents Ia to Ic are ahead, delayed, or matching phases with respect to the phase voltages Va to Vc) is correct (coincides with the set relation).

Here, whether the phase currents Ia to Ic are ahead, delayed, or matching phases with respect to the phase voltages Va to Vc depends on the load connected to the three-phase, four-wire power source. When the load is inductive, the phase currents Ia to Ic are the leading phases that occur ahead of the phase voltages Va to Vc. When the load is capacitive, the phase currents Ia to Ic have the delayed phase with respect to the phase voltages Va to Vc. Furthermore, when the load is neither inductive nor capacitive, the phase currents Ia to Ic have the matching phase with that of the phase voltages Va to Vc. Knowing that the load connected to the three-phase, four-wire power source is inductive, capacitive, neither of them in advance, the phase relation in the respective phases can be set using the operator 13 to, for example, the relation that “the phase currents Ia to Ic are delayed in phase with respect to the corresponding phase voltages Va to Vc.”

The operator 13 shown in FIG. 1 has, for example, a keyboard and is used to set various kinds of information to be stored in the storage 12.

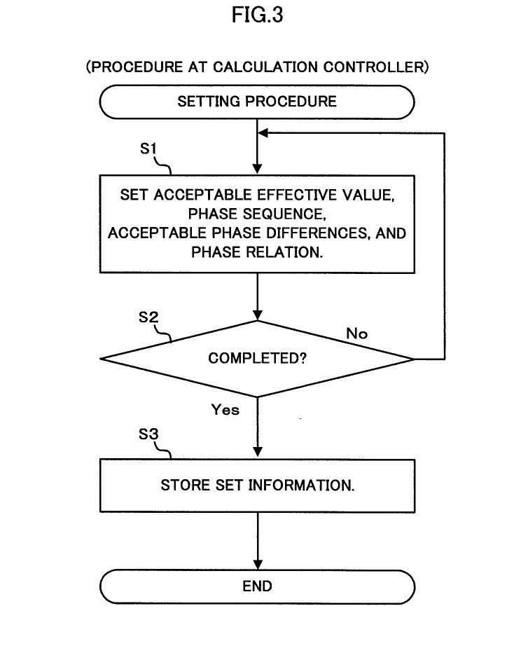

The setting procedure executed by the calculation controller 10 of the power measuring device 1 will be described hereafter with reference to FIG. 3. The setting procedure starts when the power measuring device 1 is powered on and a setting execution operation is conducted by the operator 13.

In the setting procedure, first, the calculation controller 10 receives setting using the operator 13 on the acceptable effective value (an acceptable effective value range of the phase voltages Va to Vc), the phase sequence of the phase voltages Va to Vc, the acceptable phase differences (acceptable phase difference ranges), and the phase relation (whether the phase currents Ia to Ic are ahead, delayed, or matching phases with respect to the phase voltages Va to Vc) (Step S1).

Subsequently, if the reception of setting is not completed (Step S2: No), the calculation controller 10 returns to the Step S1. On the other hand, if the reception of setting is completed (Step S2: Yes), the calculation controller 10 stores the set acceptable effective value in the acceptable voltage storage 126, the set phase sequence in the set phase sequence storage 127, the set acceptable phase differences in the acceptable phase difference storage 128, and the set phase relation in the set phase relation storage 129 (Step S3), and ends the setting procedure.

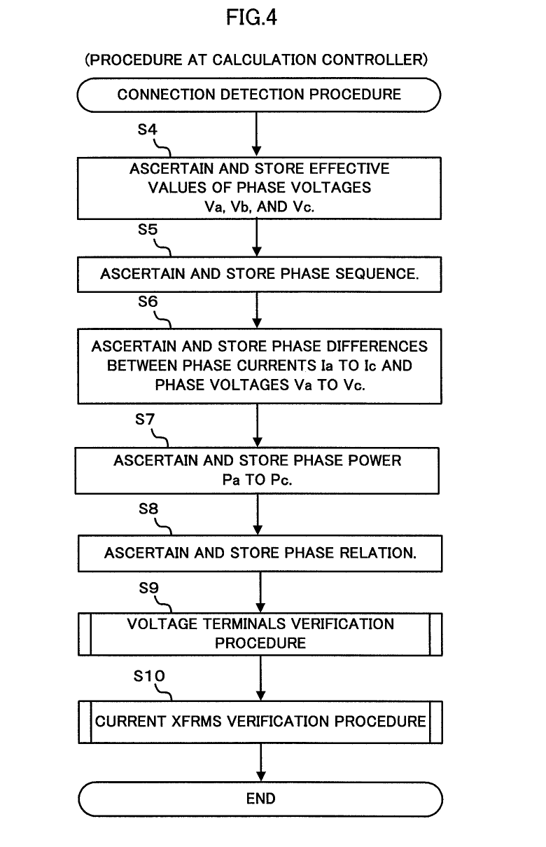

The connection detection procedure executed by the calculation controller 10 of the power measuring device 1 will be described hereafter with reference to FIG. 4. The connection detection procedure starts when the power measuring device 1 is powered on and an execution operation is conducted by the operator 13. The calculation controller 10 verifies the connection of the voltage terminals 3a to 3d and the placement of the current xfmrs 4a to 4c in the connection detection procedure.

In the connection detection procedure, first, the calculation controller 10 (voltage verifier 101) calculates the effective values of the phase voltages Va, Vb, and Vc, and stores the calculated effective values in the calculated voltage storage 121 (Step S4).

The voltage verifier 101 calculates the effective values of the phase voltages Va to Vc as follows. First, the voltage verifier 101 ascertains the maximum values of the partial voltages Vad, Vbd, and Vcd using the values of the partial voltages Vad to Vcd (the instantaneous values at each sampling time) stored in the RAM (not shown). Then, the calculation controller 10 ascertains the effective values of the phase voltages Va, Vb, and Vc from the ascertained maximum values of the partial voltages Vad to Vcd using a conversion table (a table for converting the maximum values of the partial voltages Vad, Vbd, and Vcd to the effective values of the phase voltages Va, Vb, and Vc) stored in the ROM (not shown) in advance. In this way, the voltage verifier 101 calculates the effective values of the phase voltages Va to Vc.

Then, the calculation controller 10 (voltage verifier 101) ascertains the phase sequence of the phase voltages Va, Vb, and Vc (the order in which the phase voltages are reached zero volt), and stores the ascertained phase sequence in the phase sequence storage 122 (Step S5).

The voltage verifier 101 ascertains the phase sequence as follows. The voltage verifier 101 ascertains the zero-crossing time of the phase voltages Va to Vc based on information stored in the RAM (not shown), namely information created by associating the values of the direct-current voltages of the respective phases that are output from the comparator 8a with the time. Then, the voltage verifier 101 compares the zero-crossing time of the phase voltages Va to Vc and ascertains the phase sequence of the phase voltages Va, Vb, and Vc (the order in which the phase voltages are reached zero volt).

Then, the calculation controller 10 (current verifier 102) calculates, for the respective phases, the phase differences between the phase currents Ia to Ic and phase voltages Va to Vc, and stores for the phases respectively, the calculated phase differences in the calculated phase difference storage 123 (Step S6).

The current verifier 102 calculates the phase differences as follows. The current verifier 102 ascertains the zero-crossing time of the phase voltages Va to Vc and the zero-crossing time of the phase currents Ia to Ic based on information stored in the RAM (not shown), namely information created by associating the values of the direct-current voltages of the respective phases that are output from the comparator 8a with the time and information created by associating the values of the direct-current voltages in the respective phases that are output from the comparator 8b with the time. The current verifier 102 calculates, for the respective phases, the phase differences between the phase currents Ia to Ic and phase voltages Va to Vc (0 degree to 180 degrees) based on the zero-crossing times of the phase currents Ia to Ic and phase voltages Va to Vc.

Then, the calculation controller 10 (current verifier 102) calculates the phase power Pa to Pc and stores the calculated phase power Pa to Pc in the calculated power storage 124 (Step S7).

The current verifier 102 calculates the phase power Pa to Pc as follows. First, the current verifier 102 converts the values of the partial voltages Vad to Vcd (the instantaneous values at the time of sampling) stored in the RAM (not shown) to the instantaneous values of the phase voltages Va to Vc using a conversion table stored in the ROM (not shown) in advance, more specifically a table for converting the values of the partial voltages Vad to Vcd (the instantaneous values at the time of sampling) to the instantaneous values of the phase voltages Va to Vc. Similarly, the current verifier 102 converts the values of the converted voltages Via to Vic (the instantaneous values at the time of sampling) stored in the RAM (not shown) to the instantaneous values of the phase currents Ia to Ic using a conversion table stored in the ROM (not shown) in advance, more specifically a table for converting the values of the converted voltages Via to Vic (the instantaneous values at the time of sampling) to the instantaneous values of the phase currents Ia to Ic. Then, the current verifier 102 integrates the products of the phase voltages Va to Vc and phase currents Ia to Ic obtained using the conversion table over one cycle of the phase voltages Va to Vc to calculate the phase power Pa to Pc.

Then, the calculation controller 10 (phase relation verifier 103) ascertains the phase relation that the phase currents Ia to Ic are ahead, delayed, or matching phases with respect to the phase voltages Va to Vc (the phase relation of the phase currents Ia to Ic with the phase voltages Va to Vc) for the respective phases, and stores the ascertained phase relation in the phase relation storage 125 for the respective phases (Step 8).

The phase relation verifier 103 ascertains the phase relation in the respective phases as follows. First, the phase relation verifier 103 reads time at which the partial voltage Vad (corresponding to the phase voltage Va) is changed from a positive direct-current voltage to a voltage of zero (a zero-crossing time) and time at which the converted voltage Vic (corresponding to the phase current Ia) changes from a positive direct-current voltage to a voltage of zero (a zero-crossing time), based on the information stored on the RAM (not shown), in other words, the information created by associating the values of the output voltages of the comparator 8a with time, and the information created by associating the values of the output voltages of the comparator 8b with time. Then, the phase relation verifier 103 compares the zero-crossing time of the phase voltage Va and phase current Ia and determines whether the phase current Ia is ahead, delayed, or matching phases with respect to the phase voltage Va. Similarly, the phase relation verifier 103 ascertains the phase relation between the phase current Ib and phase voltage Vb and the phase relation between the phase current Ic and phase voltage Vc. In this way, the phase relation verifier 103 ascertains the phase relation of the phase currents Ia to Ic with the phase voltages Va to Vc for the respective phases.

After executing the Step S8, the calculation controller 10 proceeds to Step S9.

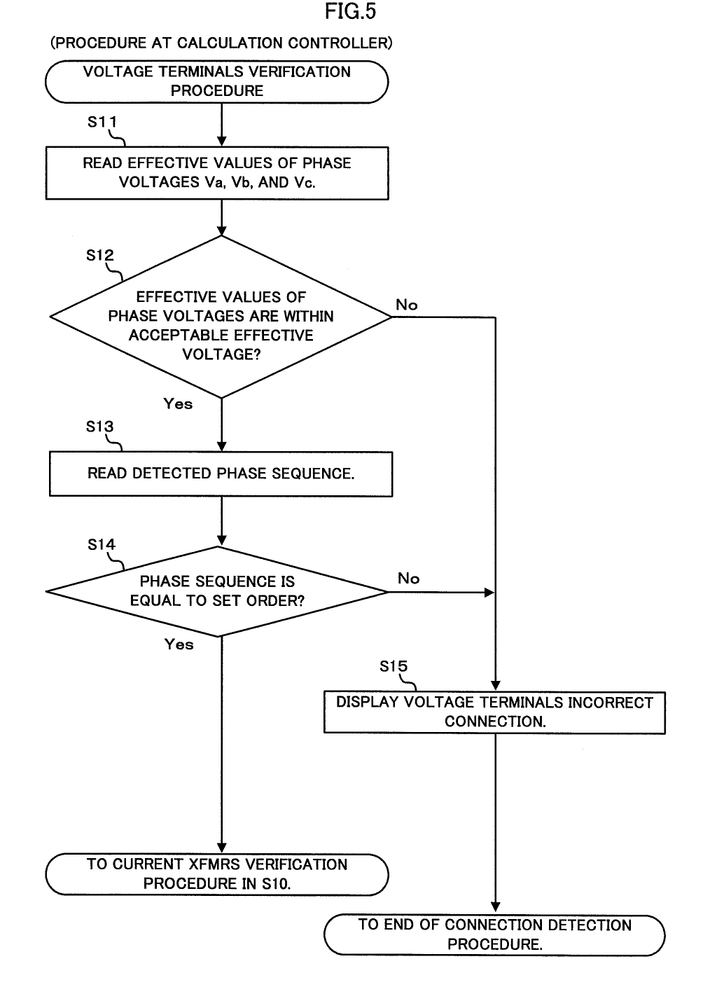

The voltage terminals verification procedure executed in the Step S9 will be described with reference to FIG. 5. Here, the voltage terminals verification procedure is a procedure to verify whether the voltage terminals 3a to 3d are connected to the power lines 2a to 2d correctly.

In the voltage terminals verification procedure, the calculation controller 10 (voltage verifier 101) reads the effective values of the phase voltages Va to Vc stored in the calculated voltage storage 121 (Step S11), and determines whether the read effective values are within an acceptable effective value range stored in the acceptable voltage storage 126 (Step S12).

If the effective values are all within the acceptable effective value range (Step S12: Yes), the calculation controller 10 (voltage verifier 101) reads the phase sequence (the phase sequence of the phase voltages Va to Vc ascertained by the calculation controller 10) stored in the phase sequence storage 122 (Step S13), and determines whether the read phase sequence coincides with the set phase sequence store in the set phase sequence storage 127 (Step S14).

If the phase sequence is equal to the phase sequence store in the set phase sequence storage 127 (Step S14: Yes), the calculation controller 10 (voltage verifier 101) assumes that the current terminals 3a to 3d are connected to the power lines 2a to 2d correctly and proceeds to the current xfrms verification procedure in Step S5.

On the other hand, if the phase sequence is different from the phase sequence stored in the set phase sequence storage 127 in the Step S14 (Step S14: No), the calculation controller 10 (voltage verifier 101) assumes that any of the voltage terminals 3a to 3d is connected incorrectly and proceeds to Step S15.

The calculation controller 10 displays a message on the notifier 11 indicating that any of the voltage terminals 3a to 3d is connected incorrectly (Step S15), and ends the connection detection procedure.

On the other hand, if at least one of the effective values is outside the acceptable effective value range in the Step S12 (Step S12: No), the calculation controller 10 (voltage verifier 101) assumes that any of the voltage terminals 3a to 3d is connected incorrectly and proceeds to the Step S15.

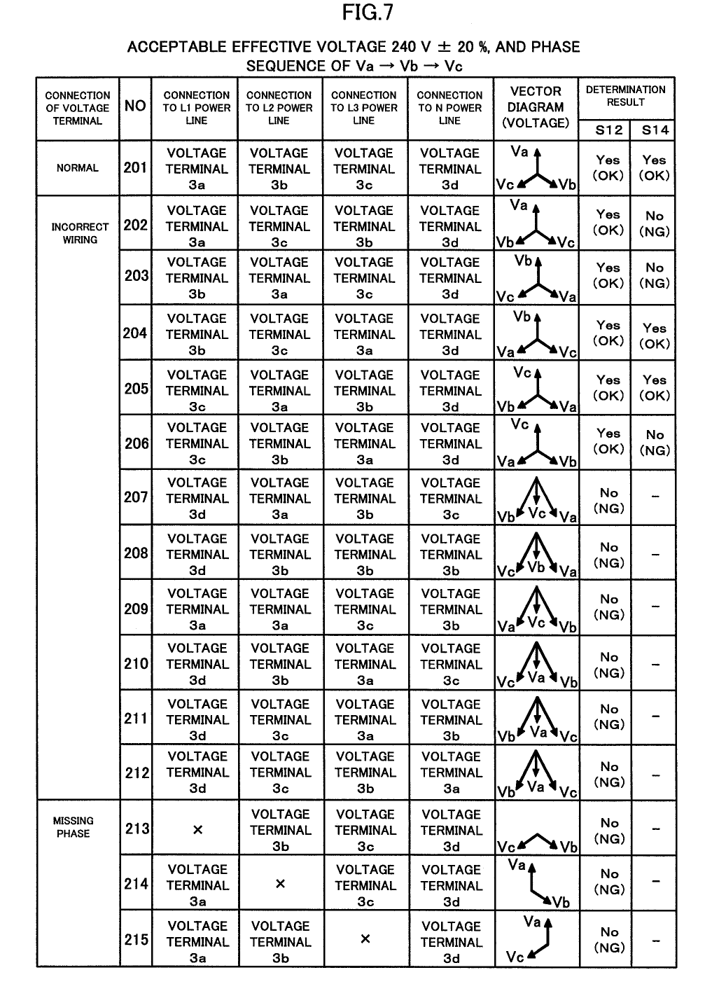

Incorrect connection of the voltage terminals 3a to 3d that is detectable in the voltage terminals verification procedure will be described with reference to FIG. 7. Here, in FIG. 7, Nos. 202 to 215 refer to incorrect connection of the voltage terminals 3a to 3d and No. 201 refers to correct connection of the voltage terminals 3a to 3d.

Furthermore, the explanation of FIG. 7 will be made on the assumption that the three-phase, four-wire power source is 415 volts (line voltage), the acceptable effective value in each phase stored in the acceptable voltage storage 127 is “240 volts (415 volts×1/√3)±20%,” and the phase sequence stored in the set phase sequence storage 128 is “the order of Phase voltage Va→Phase voltage Vb→Phase voltage Vc.”

No. 201 refers to the case in which the voltage terminals 3a to 3d are connected to the power lines 2a to 2d correctly; therefore, the effective values of the phase voltages Va to Vc stored in the calculated voltage storage 121 are measured to be an effective value of 240 volts (415 volts×1/√3) upon correct connection. Then, the calculation controller 10 (voltage verifier 101) determines whether the effective values are within the acceptable range, namely Yes in the Step S12. Furthermore, since the voltage terminals 3a to 3d are connected correctly, the phase sequence stored in the phase sequence storage 122 is Phase voltage Va→Phase voltage Vb→Phase voltage Vc. Then, the calculation controller 10 (voltage verifier 101) determines that the phase sequence coincides with the set order, namely Yes in the Step S14, and proceeds to the Step S5.

Incorrect connection of Nos. 202 to 212 refers to cases in which the voltage terminals 3a to 3d are wired to the power lines 2a to 2d incorrectly (incorrect wiring cases).

For example, in the incorrect wiring of No. 207, the voltage terminal 3d is connected to the L1 power line 2a, the voltage terminals 3a and 3b are connected to the L2 power line 2b and L3 power line 2c, respectively. Then, the effective values of the phase voltages Va and Vb stored in the calculated voltage storage 121 are a line voltage of 415 volts, which is different from the effective value of 240 volts upon correct connection. Then, the calculation controller 10 (voltage verifier 101) determines that the effective values are outside the acceptable range, namely No in the Step S12, and proceeds to the Step S15. This applies also to the incorrect wiring of Nos. 208 to 212.

On the other hand, for example, in the incorrect wiring of No. 202, the effective values of the phase voltages Va to Vc stored in the calculated voltage storage 121 are 240 volts, which is within the acceptable effective voltage. Then, the calculation controller 10 (voltage verifier 101) determines that the effective values are within the acceptable range, namely Yes in the Step S12. However, in the case of No. 202, the voltage terminal 3b is connected to the L3 power line 2c and the voltage terminal 3c is connected to the L2 power line 2b. Therefore, the phase sequence stored in the phase sequence storage 122 is Phase voltage Va→Phase voltage Vc→Phase voltage Vb (see the vector diagram). Then, the calculation controller 10 (voltage verifier 101) determines that the phase sequence does not coincide with the set sequence, namely No in the Step S14, and proceeds to the Step S15. This applies also to the incorrect wiring of Nos. 203 and 206.

Here, in the incorrect wiring of Nos. 204 and 205, the voltage terminals 3a to 3c are connected to the lines shifted one by one and the phase sequence coincides with the set sequence. Then, the determination result is Yes in the Steps S12 and S14 and the voltage terminals verification procedure (Step S4) fails the detection. However, this incorrect connection is verified in the current xfmrs verification procedure (Step S5) described later.

In the incorrect connection of Nos. 213 to 215, the voltage terminals 3a to 3c are not connected to the power lines 2a to 2c (missing phase cases). For example, in the missing phase of No. 213, the voltage terminal 3a is not connected to the L1 power line 2a and therefore, the effective value of the phase voltage Va stored in the calculated voltage storage 121 is zero volt (see the vector diagram). Then, the calculation controller 10 (voltage verifier 101) determines that the effective values are outside the acceptable range, namely No in the Step S12, and proceeds to the Step S15. This applies also to the missing phase of Nos. 214 and 215.

Returning to FIG. 4, after the voltage terminals verification procedure in the Step S9 ends, the calculation controller 10 executes the current xfrms verification procedure in Step S10.

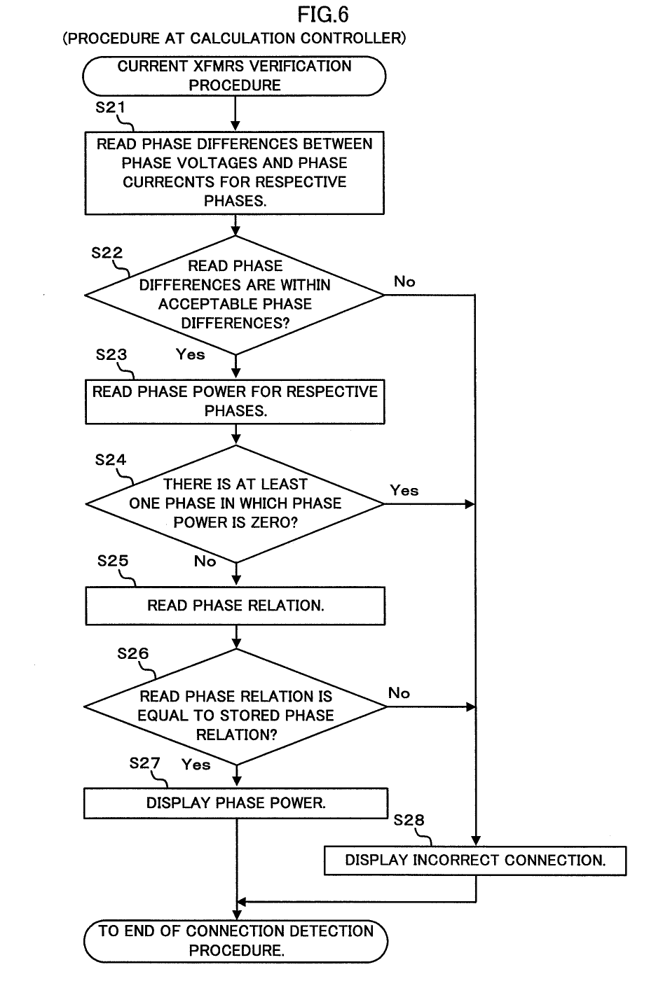

The current xfrms verification procedure executed in the Step S10 will be described with reference to FIG. 6. Here, the current xfrms verification procedure is a procedure to verify whether the current xfmrs 4a to 4c are arranged correctly and to detect the incorrect wiring of Nos. 204 and 205 in FIG. 7.

In the current xfrms verification procedure, the calculation controller 10 (current verifier 102) reads for the respective phases, the phase differences between the phase voltage Va to Vc and phase current Ia to Ic stored in the calculated phase difference storage 123 (Step S21). Then, the calculation controller 10 (voltage verifier 102) determines whether the read phase differences in the respective phases are all within the acceptable phase difference ranges stored in the acceptable phase difference storage 128 for the respective phases (Step S22).

If the phase differences in the respective phases are all within the acceptable phase difference ranges (Step S22: Yes), the calculation controller 10 (current verifier 102) assumes that there is no problem with the phase differences in the respective phases and proceeds to Step S23.

In the Step S23, the calculation controller 10 (current verifier 102) reads the phase power Pa to Pc in the respective phases stored in the calculated power storage 124 (Step S23), and determines whether there is at least one phase in which the phase power is zero (Step S24).

If there is no phase in which the phase power is zero (Step S24: No), the calculation controller 10 (current verifier 102) proceeds to Step S25 in which the phase relation is verified. On the other hand, if there is at least one phase in which the phase power is zero (Step S24: Yes), the calculation controller 10 (current verifier 102) proceeds to Step S28.

On the other hand, in the Step S22, if at least one of the phase differences in the respective phases read in the Step S21 is outside the acceptable phase difference range stored in the acceptable phase difference storage 128 (Step S22: No), the calculation controller 10 (current verifier 102) proceeds to Step S28.

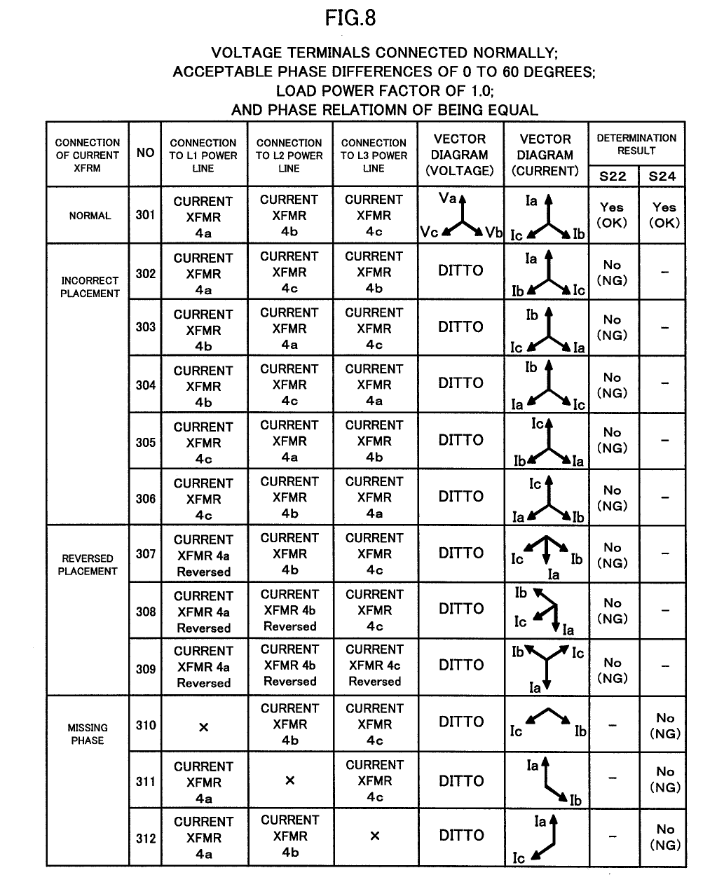

Incorrect arrangement of the current xfmrs 4a to 4c that is detectable in the above procedure will be described with reference to FIG. 8. Here, the explanation of FIG. 8 will be made on the assumption of the following conditions.

The voltage terminals 3a to 3d are respectively connected to the power lines 2a to 2d correctly. Furthermore, since the power factor of the load connected to the three-phase, four-wire power source is generally 0.5 to 1.0, in consideration of this matter, the power factor of the load is assumed to be 1.0. Furthermore, since the power factor of the load is generally 0.5 to 1.0 as mentioned above, the phase differences between the phase voltages Va to Vc and phase currents Ia to Ic of the respective phases are equal to or greater than 0 degree and less than 60 degrees. Then, the acceptable phase differences stored in the acceptable phase difference storage 128 are assumed to be equal to or greater than 0 degree and less than 60 degrees as well. Finally, the phase relation resulting from the load connected to the three-phase, four-wire power source being inductive or capacitive, namely the phase relation (whether the phase currents Ia to Ic are ahead, delayed, or matching phases with respect to the phase voltages Va to Vc) stored in the set phase relation storage 129 is assumed to be the matching phase based on the assumption that the power factor of the load is 1.0.

Nos. 302 to 312 refer to incorrect arrangement of the current xfmrs 4a to 4c and No. 301 refers to correct arrangement of the current xfmrs 4a to 4c.

No. 301 refers to the case in which the current xfmrs 4a to 4c are placed on the power lines 2a to 2c correctly. Then, when the power factor of the load is 1.0, the phase differences between the phase voltages Va to Vc and phase currents Ia to Ic are zero. Then, the calculation controller 10 (current verifier 102) determines that the phase differences are within the acceptable ranges, namely Yes in the Step S22. Furthermore, the phase power Pa to Pc stored in the calculated power storage 124 is not zero in any phase. Then, the calculation controller 10 (current verifier 102) determines that there is no phase in which the phase power is zero, namely No in the Step S24. Here, if the power factor of the load is 0.5, the phase differences between the phase voltages Va to Vc and phase current Ia to Ic are less than 60 degrees. Then, the calculation controller 10 (current verifier 102) determines the result to be Yes in the Step S22 and the result to be No in the Step S24 as in the above case.

Incorrect connection of Nos. 302 to 306 refers to cases in which the current xfmrs 4a to 4c are incorrectly arranged on the power lines 2a to 2c (incorrect arrangement cases). For example, in the incorrect arrangement of No. 302, the current xfmr 4c is arranged on the L2 power line 2b and the current xfmr 4b is arranged on the L3 power line 2c. Then, when the power factor of the load is 1.0, there is no phase difference between the phase voltage Va and phase current Ia; however, the phase difference between the phase voltage Vb and phase current Ib and the phase difference between the phase voltage Vc and phase current Ic are 120 degrees (see the voltage and current vector diagrams). Then, the calculation controller 10 (current verifier 102) determines that the phase differences are outside the acceptable ranges, namely No in the Step S22, and proceeds to the Step S28. Here, if the power factor of the load is 0.5, the phase difference between the phase voltage Va and phase current Ia and the phase difference between the phase voltage Vb and phase current Ib are less than 60 degrees but the phase difference between the phase voltage Vc and phase current Ic is 180 degrees. Then, the calculation controller 10 (current verifier 102) determines that the phase differences are outside the acceptable ranges, namely No in the Step S22 as in the above case. This applies also to the incorrect placement of Nos. 303 to 306.

Incorrect connection of Nos. 303 to 309 refers to cases in which the primary conductors of the current transformers of the current xfmrs 4a to 4c are reversely arranged with respect to the running direction of the phase currents Ia to Ic (reversed placement cases). For example, in the reversed arrangement of No. 307, the current xfmr 4a is reversely arranged with respect to the orientation of the phase current Ia. When the power factor of the load is 1.0, the phase difference between the phase voltage Vb and phase current Ib and the phase difference between the phase voltage Vc and phase current Ic are less than 60 degrees but the phase difference between the phase voltage Va and phase current Ia is 180 degrees (see the voltage and current vector diagrams). Then, the calculation controller 10 (current verifier 102) determines that the phase difference is outside the acceptable range, namely No in the Step S22, and proceeds to the Step S28. Here, if the power factor of the load is 0.5, the phase difference between the phase voltage Vb and phase current Ib and the phase difference between the phase voltage Vc and phase current Ic are less than 60 degrees but the phase difference between the phase voltage Va and phase current Ia is 120 degrees. Then, the calculation controller 10 (current verifier 102) determines that the phase difference is outside the acceptable range, namely No in the Step S22 as in the above case. This applies also to the reversed arrangement of Nos. 308 and 309.

Incorrect connection of Nos. 310 to 312 refers to cases in which the current xfmrs 4a to 4c are not arranged on the power lines 2a to 2c (missing phase cases). For example, in the missing phase of No. 310, since the current xfmr 4a is not arranged on the L1 power line 2a, the phase power Pa stored in the calculated power storage 124 is zero (see the current vector diagram). Then, the calculation controller 10 (current verifier 102) determines that there is at least one phase in which the phase power is zero, namely No in the Step S24, and proceeds to the Step S28. This applies also to the missing phase of Nos. 311 and 312.

Here, the calculation controller 10 detects in the Step S22 the two patterns of incorrect connection of the voltage terminals (Nos. 204 and 205 in FIG. 7) that the calculation controller 10 has failed to detect in the voltage terminals verification procedure in the Step S4.

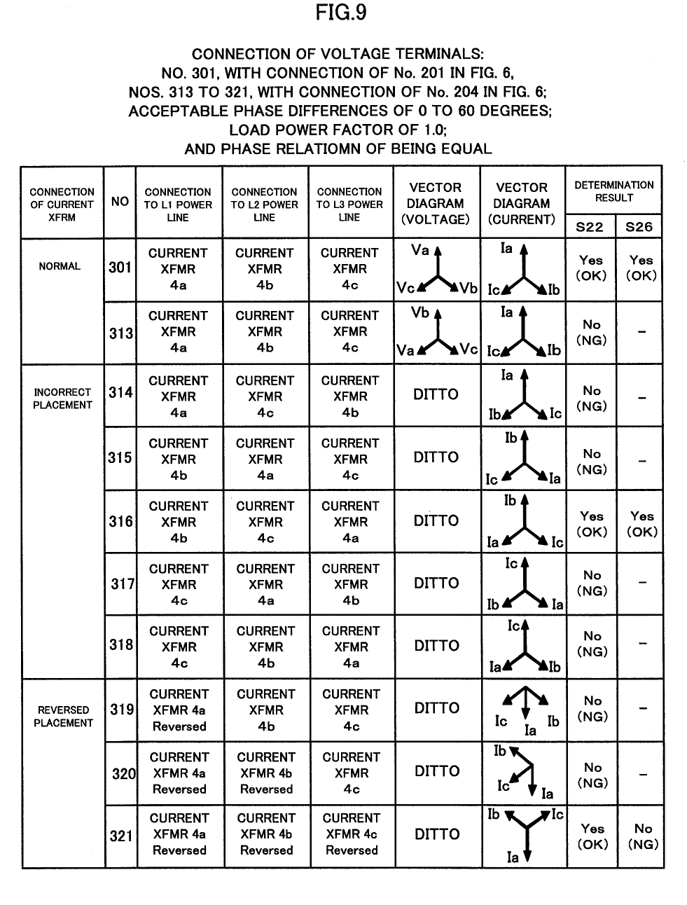

Detection of the incorrect connection of Nos. 204 and 205 in FIG. 7 will be described with reference to Nos. 313 to 321 in FIG. 9. Here, in FIG. 9, Nos. 313 to 321 refer to the case in which the voltage terminals 3a to 3d are connected incorrectly as referred to by No. 204 in FIG. 7 (No. 301 refers to the case in which the voltage terminals 3a to 3d are connected correctly, namely connected as referred to by No. 201 in FIG. 7). Furthermore, the power factor of the load is assumed to be 1.0. Furthermore, the acceptable phase differences stored in the acceptable phase difference storage 128 are equal to or greater than 0 degree and less than 60 degrees. Finally, the phase relation resulting from the load connected to the three-phase, four-wire power source being inductive or capacitive, namely the phase relation (whether the phase currents Ia to Ic are ahead, delayed, or matching phases with respect to the phase voltages Va to Vc) stored in the set phase relation storage 129 is assumed to be the matching phase based on the assumption that the power factor of the load is 1.0.

No. 313 refers to correct arrangement of the current xfmrs 4a to 4c. Nos. 315 to 318 refer to incorrect arrangement of the current xfmrs 4a to 4c. Furthermore, Nos. 319 to 321 refer to reversed arrangement of the current xfmrs 4a to 4c.

In the case of No. 313, the current xfmrs 4a to 4c are correctly arranged but the voltage terminals 3a to 3c are connected incorrectly. When the power factor of the load is 1.0, the phase differences between the phase voltages Va to Vc and phase currents Ia to Ic are 120 degrees in all phases (see the voltage and current vector diagrams). Then, the calculation controller 10 (current verifier 102) determines that the phase differences are outside the acceptable ranges, namely No in the Step S22, and proceeds to the Step S28. Here, if the power factor of the load is 0.5, the phase differences between the phase voltages Va to Vc and phase currents Ia to Ic are 180 degrees in all phases. Then, the calculation controller 10 (current verifier 102) determines that the phase differences are outside the acceptable ranges, namely No in the Step S22 as in the above case.

In the case of No. 314, the current xfmrs 4a to 4c are incorrectly arranged and the voltage terminals 3a to 3c are incorrectly connected. When the power factor of the load is 1.0, the phase voltage Vc and phase current Ic are in phase but the phase difference between the phase voltage Va and phase current Ia and the phase difference between the phase voltage Vb and phase current Ib are 120 degrees (see the voltage and current vector diagrams). Then, the calculation controller 10 (current verifier 102) determines that the phase differences are outside the acceptable ranges, namely No in the Step S22, and proceeds to the Step S28. Here, if the power factor of the load is 0.5, the phase difference between the phase voltage Va and phase current Ia and the phase difference between the phase voltage Vc and phase current Ic are less than 60 degrees but the phase difference between the phase voltage Vb and phase current Ib is 180 degrees. Then, the calculation controller 10 (current verifier 102) determines that the phase difference is outside the acceptable range, namely No in the Step S22 as in the above case. This applies also to the incorrect arrangement cases of Nos. 315, 317, and 318.

Here, the case of No. 316 is not detected as incorrect connection. However, the current xfmr 4a is placed on the L3 power line 2c, which is the same power line as the voltage terminal 3a, the current xfmr 4b is placed on the L1 power line 2a, which is the same power line as the voltage terminal 3b, and the current xfmr 4c is placed on the L2 power line 2b, which is the same power line as the voltage terminal 3c. In other words, in spite of the incorrect connection and arrangement, the combinations of the voltage terminals and current transformers are correct. Then, the phase power Pa to Pc measured by the power measuring device 1 will be correct. Therefore, there will be no problem even if the case of No. 316 is not detected.

Here, detection of the incorrect connection of No. 205 in FIG. 7 in the current xfrms verification procedure is discussed. In the case of No. 317, namely in the case in which the current xfmr 4c is placed on the L1 power line 2a, the current xfmr 4a is placed on the L2 power line 2b, and the current xfmr 4b is placed on the L3 power line 2c, unlike the case of No. 204, the power values of the phase power Pa to Pc measured by the power measuring device 1 will be correct and the connection detection procedure of this embodiment will fail the detection (on the other hand, in the case of No. 205, unlike the cases of No. 204, No. 316 is detected as incorrect connection). In the other cases of Nos. 313 to 315 and 318, the detection results of No. 205 are the same as the detection results of No. 204.

In the case of No. 319 shown in FIG. 9, the primary conductor of the current transformer of the current xfmr 4a is arranged reversely. When the power factor of the load is 1.0, the phase difference between the phase voltage Va and phase current Ia is less than 60 degrees but the phase difference between the phase voltage Vb and phase current Ib and the phase difference between the phase voltage Vc and phase current Ic are 120 degrees (see the voltage and current vector diagrams). Then, the calculation controller 10 (current verifier 102) determines that the phase differences are outside the acceptable ranges, namely No in the Step S22, and proceeds to the Step S28. Here, if the power factor of the load is 0.5, the phase difference between the phase voltage Vb and phase current Ib and the phase difference between the phase voltage Vc and phase current Ic are less than 60 degrees but the phase difference between the phase voltage Va and phase current Ia is 120 degrees. Then, the calculation controller 10 (current verifier 102) determines that the phase difference is outside the acceptable range, namely No in the Step S22 as in the above case.

Furthermore, in the case of No. 320, the primary conductors of the current transformers of the current xfmrs 4a and 4b are placed reversely. When the power factor of the load is 1.0, the phase difference between the phase voltage Va and phase current Ia and the phase difference between the phase voltage Vb and phase current Ib are less than 60 degrees but the phase difference between the phase voltage Vc and phase current Ic is 120 degrees. Then, the calculation controller 10 (current verifier 102) determines that the phase difference is outside the acceptable range, namely No in the Step S22. Here, if the power factor of the load is 0.5, the phase difference between the phase voltage Vc and phase current Ic is less than 60 degrees but the phase difference between the phase voltage Va and phase current Ia and the phase difference between the phase voltage Vb and phase current Ib are 120 degrees. Then, the calculation controller 10 (current verifier 102) determines that the phase differences are outside the acceptable ranges, namely No in the Step S22 as in the above case.

As described above, the incorrect connection of the voltage terminals 3a to 3c that is referred to by Nos. 204 and 205 in FIG. 7 is detected in the current xfrms verification procedure. More specifically, when the voltage terminals 3a to 3c are connected incorrectly as referred to by No. 204 in FIG. 7, the incorrect connection of Nos. 313 to 315 and 317 to 320 can be detected (No. 316 is excluded because the power values will be correct). On the other hand, when the voltage terminals 3a to 3c are connected incorrectly as referred to by No. 205 in FIG. 7, the incorrect connection of Nos. 313 to 316 and 318 to 320 can be detected (No. 317 is excluded because the power values will be correct).

However, in the case of No. 321, the phase differences in all phases are 60 degrees when the power factor of the load is 1.0, and 0 degree when the power factor of the load is 0.5. Then, the reversed arrangement of the primary conductors of the current transformers of the current xfmrs 4a to 4c cannot be detected in the Steps S22 and S24. This reversed arrangement can be detected in Step S25 and subsequent steps in FIG. 6 described later.

Returning to FIG. 6, if there is no phase in which the phase power is zero in the Step S24 (Step S24: No), the calculation controller 10 (current verifier 102) proceeds to Step S25.

In the Step S25, the calculation controller 10 (phase relation verifier 103) reads the phase relation in the respective phases stored in the phase relation storage 125, namely the phase relation of the currents Ia to Ic to the phase voltages Va to Vc in the respective phases (Step S25). Then, the calculation controller 10 determines whether the phase relation read in the Step S25 is equal to the phase relation stored in the set phase relation storage 129 (Step S26).

If the read phase relation is equal to the stored phase relation (Step S26: Yes), the calculation controller 10 (phase relation verifier 103) assumes that the voltage terminals 3a to 3d and current xfmrs 4a to 4c are arranged correctly, and proceeds to Step S27.

In the Step S27, the calculation controller 10 displays the phase power Pa to Pc stored in the calculated power storage 124 on the notifier 11 (Step S27), and ends the connection detection procedure.

Here, the case of proceeding to the Step S27, namely the case in which the read phase relation is determined to be equal to the phase relation stored in the set phase relation storage 129 in the Step S26 applies to the cases of Nos. 301 and 316 in FIG. 9.

More specifically, in the case of proceeding to the Step S27, as apparent from the vector diagrams of Nos. 301 and 316 shown in FIG. 9, the following conditions are satisfied: 1. the effective values of the phase voltages Va to Vc stored in the calculated voltage storage 121 are within the acceptable effective voltage stored in the acceptable voltage storage 126; 2. the phase sequence stored in the phase sequence storage 122 coincides with the phase sequence stored in the set phase sequence storage 127; 3. the phase differences between the phase voltages Va to Vc and phase currents Ia to Ic stored in the calculated phase difference storage 123 are within the acceptable phase difference ranges stored in the set phase difference storage 128; 4. the phase power Pa to Pc is not zero; and 5. the phase relation stored in the phase relation storage 125 is equal to the phase relation stored in the set phase relation storage 129, namely the voltage terminals 3a to 3d and current xfmrs 4a to 4c are arranged correctly.

Here, if the phase relation in the respective phases read in the Step S25 is not equal to the phase relation in the respective phases stored in the set phase relation storage 129 in the Step S26 (Step S26: No), the calculation controller 10 (phase relation verifier 103) determines that the primary conductors of the current transformers of the current xfmrs 4a to 4c are all arranged reversely (see No. 321 in FIG. 9).

In the case of No. 321 in FIG. 9, the phase relation read from the phase relation storage 125 indicates that the phase currents Ia to Ic are the leading phases that occur ahead of the phase voltages Va to Vc (see the voltage and current vector diagrams). Then, the calculation controller 10 (phase relation verifier 103) determines that the phase relation is different from the phase relation stored in the set phase relation storage 129 (here, the phase relation of being equal is stored) (Step No. 26: No). As in this case, the calculation controller 10 (phase relation verifier 103) can determine whether the primary conductors of the current transformers of the current xfmrs 4a to 4c are all arranged reversely by determining whether the ascertained phase relation is different from the set (stored) phase relation.

It is possible to determine that the primary conductors of the current transformers of the current xfmrs 4a to 4c are all placed reversely because the calculation controller 10 (phase relation verifier 103) determines that the phase relation is different in the Step S26 (Step S26: No) when a unique case occurs in which the voltage terminals 3a to 3d are connected correctly and the primary conductors of the current transformers of the current xfmrs 4a to 4c are all placed reversely.

After determining the result to be No in the Step S26, the calculation controller 10 executes Step S28. More specifically, the calculation controller 10 displays a message indicating that the current xfmrs 4a to 4c are arranged incorrectly or the voltage terminals 3a to 3d are connected incorrectly on the notifier 11 for notification, and ends the connection detection procedure. Here, the calculation controller 10 displays a message indicating that the voltage terminals 3a to 3d are connected incorrectly in the Step S28 because the calculation controller 10 may detect the incorrect connection of the voltage terminals 3a to 3c that is referred to by Nos. 204 and 205 in FIG. 7 in the Step S22.

As described above, the power measuring device 1 stores in the set phase relation storage 129 whether the load connected to the three-phase, four-wire power source is inductive, capacitive, or neither of them, in other words whether the phase currents Ia to Ic are ahead, delayed, or matching phases with respect to the phase voltages Va to Vc, and determines whether the stored phase relation coincides with the ascertained phase relation. Then, the incorrect connection that cannot be detected in the prior art, more specifically the primary conductors of the current transformers of the current xfmrs 4a to 4c that are all placed reversely while the voltage terminals 3a to 3d are connected correctly can be detected as incorrect arrangement. Then, the power measuring device 1 can detect incorrect connection of the voltage terminals 3a to 3d and incorrect arrangement of the current xfmrs 4a to 4c with high accuracy compared with the prior art.

An embodiment of the present disclosure is described above. The present invention is not confined to the above embodiment and various modifications and applications are available.

For example, in the above-described embodiment, it is determined whether the effective values of the phase voltages Va to Vc are within an acceptable effective voltage (see the Step S12) so as to determine whether the voltage terminals 3a to 3d are connected incorrectly. This is not restrictive. In other words, instead of determining whether the effective values of the phase voltages Va to Vc are within an acceptable effective voltage, it can be determined by the calculation controller 10 whether the phase difference between the phase voltage Va and phase voltage Vb, phase difference between the phase voltage Vb and phase voltage Vc, and phase difference between the phase voltage Vc and phase voltage Va are all within a presumably equal range so as to detect incorrect connection of the voltage terminals 3a to 3d. Such determination allows the calculation controller 10 to detect incorrect connection of the voltage terminals 3a to 3d because not all phase differences are within a presumably same range in the cases of Nos. 207 to 215 in FIG. 7 (see the vector diagrams).

Furthermore, in the above-described embodiment, the calculation controller 10 ascertains the phase sequence of the phase voltages Va, Vb, and Vc from information stored in the RAM (not shown), namely information created by associating the values of the output voltages of the comparator 8a with time, and information created by associating the values of the output voltages of the comparator 8b with time, calculates the phase differences between the phase currents Ia to Ic and phase voltages Va to Vc, and ascertains the phase relation of the phase currents Ia to Ic to the phase voltages Va to Vc. This is not restrictive. In other words, the calculation controller 10 can use the values of the partial voltages Vad to Vcd (corresponding to the phase voltages Va to Vc) and the values of the converted voltages Via to Vic (corresponding to the phase currents Ia to Ic) output from the A/D converter 9 to ascertain the phase sequence, phase differences, and phase relation.

More specifically, the calculation controller 10 first stores in the RAM (not shown) the values of the partial voltages Vad to Vcd and the values of the converted voltages Via to Vic output from the A/D converter 9 in association with time, and ascertains time at which the voltages have reached maximum (or minimum) value. Subsequently, the calculation controller 10 ascertains a sequence in which the partial voltages Vad to Vcd have reached maximum (or minimum) value to ascertain the phase sequence of the phase voltages Va, Vb, and Vc. Furthermore, the calculation controller 10 calculates the phase differences between the phase currents Ia to Ic and phase voltages Va to Vc (0 degree to 180 degrees) from the time differences between the maximum (or minimum) values of the partial voltages Vad to Vcd and converted voltages Via to Vic in the respective phases. Furthermore, the calculation controller 10 determines whether the phase currents Ia to Ic are ahead, delayed, or matching phases with respect to the phase voltages Va to Vc from time at which the partial voltages Vad to Vcd and converted voltages Via to Vic have reached maximum (or minimum) value. With such configuration, the comparators 8a and 8b can be eliminated.

Furthermore, in the above-described embodiment, the supply source of the alternating-current power measured by the power measuring device 1 (the application target of the present invention) is a three-phase, four-wire power source. This is not restrictive. In other words, the supply source of the alternating-current power measured by the power measuring device 1 can be a three-phase, three-wire power source. In the case of a three-phase, three-wire power source, the N power line 2d is eliminated and then the voltage terminal 3d of the power measuring device 1 is unnecessary. Furthermore, the voltmeter 6 of the power measuring device 1 has three input terminals, which are connected to the L1 to L3 power lines 2a to 2c via the voltage terminals 3a to 3c, respectively. Additionally, one of the two input terminals of the power source 5 of the power measuring device 1 is connected to the voltage terminal 3a and the other input terminal is connected either to the voltage terminal 3b or to the voltage terminal 3c. With this configuration, the power measuring device 1 can measure the alternating-current power supplied from a three-phase, three-wire power source.

Incidentally, in the above embodiment, the programs executed by the calculation controller 10 can be stored and distributed on a computer-readable recording medium such as a flexible disc, CD-ROM (compact disc read-only memory), DVD (digital versatile disc), and MO (magneto-optical disc), and installed on a computer or the like to configure a power measuring device executing the procedures shown in FIGS. 3 to 6.

Furthermore, the programs can be stored in a disc device or the like of a given server unit on a communication network such as the Internet and, for example, superimposed on a carrier wave and downloaded.

Furthermore, when the procedures described above and shown in FIGS. 3 to 6 are realized by an OS (operating system) in part or realized by cooperation of an OS and application, only the non-OS part can be stored and distributed on a medium, or downloaded.

Various embodiments and modifications are available to the present invention without departing from the broad sense of spirit and scope of the present invention. The above-described embodiment is given for explaining the present invention and does not confine the scope of the present invention. In other words, the scope of the present invention is set forth by the scope of claims, not by the above-described embodiment. Various modifications made within the scope of claims and scope of significance of the invention equivalent thereto are considered to fall under the scope of the present invention.

### INDUSTRIAL APPLICABILITY

The present invention is suitable for realizing high accuracy of error detection.

1. A determination device, comprising:
a voltmeter for measuring alternating-current voltages of respective phases that are applied across power lines via terminals connected to the power lines transferring an alternating-current power supplied from a three-phase alternating-current power source;
a current meter for measuring the alternating currents of the respective phases that flow through the power lines via current transformers disposed at an outer circumference of the power lines; and
a phase relation verifier for ascertaining a phase relation of the alternating currents with the alternating-current voltages for the respective phases based on the alternating currents measured by the current meter and the alternating-current voltages measured by the voltmeter, and confirming a non-conformity indicating an incorrect connection of the terminals or an incorrect arrangement of the current transformers unless the phase relation ascertained for the respective phases coincides with a preset relation.

2. The determination device according to claim 1, comprising:
a phase relation storage for storing the phase relation of the alternating currents with the alternating-current voltages, storing thereof as the preset relation,
wherein the phase relation verifier compares the phase relation ascertained for the respective phases with the phase relation stored in the phase relation storage and ascertains whether the ascertained phase relation coincides with the preset relation.

3. The determination device according to claim 2, wherein
the phase relation storage stores the phase relation, that is, whether the alternating currents are ahead, delayed, or matching phases with respect to the alternating-current voltages as the phase relation.

4. (canceled)

5. The determination device according to claim 4, wherein
the notifier notifies the power for the respective phases that is ascertained by the current verifier when the voltage verifier, current verifier, and phase relation verifier all confirm the conformity.

6. The determination device according to claim 4, wherein
the notifier notifies the occurrence of the incorrect connection of the terminals when the voltage verifier confirms the non-conformity.

7. A determination method, comprising:
a phase relation verification step in which a determination device confirms a non-conformity indicating an incorrect connection of terminals or an incorrect arrangement of current transformers unless a phase relation of alternating currents with alternating-current voltages for the respective phases that is ascertained based on alternating-current voltages of the respective phases, that are measured via terminals connected to power lines transferring an alternating-current power that is supplied from a three-phase alternating-current power source and based on the alternating currents on the respective phases that are measured by current transformers disposed at an outer circumference of the power lines, coincides with a preset relation.

8. A non-transitory recording medium allowing a computer to realize:
a phase relation verification function of confirming a non-conformity indicating an incorrect connection of the terminals or an incorrect arrangement of the current transformer unless a phase relation of alternating currents with alternating-current voltages for respective phases ascertained based on alternating-current voltages of respective phases, that are measured via terminals connected to power lines transferring an alternating-current power supplied from a three-phase alternating-current power source and, alternating currents of the respective phases that are measured by current transformers disposed at an outer circumference of the power lines, coincides with a preset relation.

9. The determination device according to claim 1, further comprising:
a voltage verifier for ascertaining a vector relation of the measured alternating-current voltages for the respective phases measured by the voltmeter, and confirming a conformity when the ascertained vector relation coincides with the vector relation for the alternating-current voltages that is applied across the power lines by the three-phase alternating-current power source;
a current verifier for ascertaining the phase differences between the alternating currents and the alternating-current voltages for the respective phases, based on the alternating currents of the respective phases measured by the current meter and the alternating-current voltages of the respective phases measured by the voltmeter, and also ascertaining a power for the respective phases, and confirming a conformity when the phase differences of the respective phases are within preset, given ranges and the power for the respective phases is a positive value;
a notifier for notifying an occurrence of an incorrect connection of the terminals or an incorrect arrangement of the current transformers when at least one of the voltage verifier, current verifier, and phase relation verifier confirm a non-conformity.
